(19) United States
(12) Patent Application Publication
(10) Pub. No.: US 2002/0125471 A1
(43) Pub. Date: Sep. 12, 2002

(54) CMOS inverter circuits utilizing strained silicon surface channel MOSFETS

(76) Inventors: Eugene A. Fitzgerald, Windham, NH (US); Nicole Gerrish, Cambridge, MA (US)

Correspondence Address: Samuels, Gauthier & Stevens LLP, Suite 3300, 225 Franklin Street, Boston, MA, 02110, US

(21) Appl. No.: 10/005,274

(22) Filed: Dec. 4, 2001

Related U.S. Application Data
(63) Continuation-in-part of application No. 09/884,172, filed on Jun. 19, 2001.
(63) Continuation-in-part of application No. 09/884,517, filed on Jun. 19, 2001.
(60) Provisional application No. 60/250,985, filed on Dec. 4, 2000.

(51) Int. Cl. H01L 21/84; H01L 31/072; H01L 27/12; H01L 29/76

(52) U.S. Cl. 257/19; 257/192; 257/194; 438/285; 438/590; 257/369; 438/199; 257/351; 438/153; 257/616; 438/752; 257/20

(57) ABSTRACT

A CMOS inverter having a heterostructure including a Si substrate, a relaxed Si₁₋ₓGeₓ, layer on the Si substrate, and a strained surface layer on said relaxed Si₁₋ₓGeₓ, layer; and a pMOSFET and an nMOSFET, wherein the channel of said pMOSFET and the channel of the nMOSFET are formed in the strained surface layer. Another embodiment provides an integrated circuit having a heterostructure including a Si substrate, a relaxed Si₁₋ₓGeₓ, layer on the Si substrate, and a strained layer on the relaxed Si₁₋ₓGeₓ, layer; and a p transistor and an n transistor formed in the heterostructure, wherein the strained layer comprises the channel of the n transistor and the p transistor, and the n transistor and the p transistor are interconnected in a CMOS circuit.

### PRIORITY INFORMATION

This application claims priority from provisional application Ser. No. 60/250,985 filed Dec. 4, 2000.

This application is a continuation-in-part of patent applications Ser. No. 09/884,172 and Ser. No. 09/884,517, both filed Jun. 19, 2001.

### BACKGROUND OF THE INVENTION

The invention relates to the field of strained silicon (silicon where the crystallographic structure has been modified to increase carrier mobility) surface channel MOSFETs (Metal Oxide Semiconductor Field Effect Transistors), and, in particular, to using these MOSFETs in CMOS (Complimentary Metal Oxide Semiconductor which contain both a NMOS and PMOS device) inverters (a circuit where the output waveform rises and falls with the opposite waveform at the input) as well as in other integrated circuits. Inverter circuits are used as basic building blocks of all Very Large Scale Integrated (VLSI) designs since they allow for a basic switch (on or off state device). Hence, a basic inverter circuit of VLSI design can be used ubiquitously. The design of these CMOS inverters are so essential to VLSI design that detail trade-offs are made between the types of substrates used, the size of the devices used in the basic CMOS inverter circuit, as well as the semiconductor processing equipment and semiconductor materials used to make these devices.

From the 1970's to the year 2001, gate lengths (the physical distance between the source and the drain of a MOSFET device) have decreased by two orders of magnitude in order to speed up MOSFET devices. This decrease of gate lengths has resulting in a 30% improvement in the price/performance per year as well as drastically improved density (number of MOSFET devices per unit area) and has drastically reduced the power needs of the devices.

One way to increase the speed, improve density and lower power of the MOSFET devices is to shrink the MOSFET devices to smaller physical dimensions by moving the devices source and drain regions closer together (smaller MOSFET gate length). This has been the main direction of the semiconductor industry and this has been successfully implemented by enhancing and improving the semiconductor process technology, e.g. optical photolithography tools, defect cleaning tools, etc., and enhancing and improving the semiconductor materials e.g. photoresist materials, metallurgical materials, etc.

As MOSFET device sizes are made smaller and are designed in the sub-micron regime, the associated cost of new semiconductor tools and semiconductor materials can be prohibitive. For instance, a new state of the art CMOS facility utilizing these new semiconductor tools and semiconductor materials for use in semiconductor fabrication can cost more than $2 billion dollars per semiconductor fabrication plant. This is a large investment of money considering that the semiconductor processing equipment and the semiconductor materials are generally only useful for two scaling generations (3-4 years).

In addition to economic constraints, physically shrinking device size is quickly approaching solid state physics constraints of the device materials. Fundamental solid state physics limitations such as gate oxide leakage and source/drain resistance, make continued minimization beyond 0.1 micrometers (μm) gate length difficult if not impossible to maintain.

In order to cope with both the costs of advanced semiconductor processing tooling and equipment and the costs of the semiconductor materials and the limitations of the solid state physics limitations, semiconductor researchers are actively seeking new substrate materials that are enhancements over bulk silicon. These new substrate materials may allow the MOSFET device to obtain increases in speed and reductions in power without necessarily shrinking device size. These enhancements may lessen or put off new semiconductor processing tooling and new semiconductor materials for a generation..

One new substrate material used in the art to enhance speed and reduce power is the use of Gallium Arsenide (GaAs), which has higher electron mobility than the bulk silicon substrate materials. However, there is a limitation in the use in Complimentary FET devices (required for circuit design) where there are both N doped FET's (NFET's) where electron flow is predominant and P doped FET's (PFET's) where hole flow is predominant. The NFET devices will have higher speed because of the higher electron mobility in GaAs, but the PFET devices do not see the larger increase in their speed since the hole mobility is not dramatically enhanced. This limitation causes an asymmetry problem for complementary FET architecture uses in circuits, like inverters.

In addition to this limitation, there is a further limitation since the GaAs devices are usually fabricated with Schottky gates, which have larger leakage currents. These leakage currents are orders of magnitudes higher than MOS structures. The excess leakage causes a limitation since it leads to an increase in the “off-state” power consumption of circuits, which makes it unacceptable for highly functional circuits. Schottky gates have a further limitation in that the processing does not allow for self-aligned gate technology, which is enjoyed by MOS structures, and thus typically FETs on GaAs have larger gate-to-source and gate-to-drain resistances. Finally, an additional limitation is that GaAs processing does not enjoy the same economies of scale that have caused silicon technologies to thrive, since they are not widely used in high volume semiconductor processing. As a result, wide-scale production of GaAs circuits would be extremely costly to implement.

Another new substrate material used in the art to enhance speed and reduce power is the use of fabricating devices on silicon-on-insulator (SOI) substrates. In a SOI substrate based device, a buried oxide layer prevents the device channel from being fully depleting. Partially depleted devices offer improvements in the junction area capacitance, the device body effect, and the gate-to-body coupling capacitances, all which lead to faster devices and lower power devices. In the best-case scenario, these device improvements will result in up to 18% enhancement in circuit speed. However, there is a limitation since this improved performance comes at a cost. The partially depleted floating body of the FET device causes an uncontrolled lowering of the threshold voltage, known as the floating body effect. This phenomenon increases the off-state leakage of the transistor and thus offsets some of the potential performance advantages. Circuit designers can extract enhancements through design changes at the architectural level. However, this level of redesign can be costly and thus is not economically advantageous for all Si CMOS products.

In addition to this limitation, there is a further limitation that the reduced junction capacitance of SOI devices is less important for high functionality circuits where the interconnect capacitance is dominant. As a result, the enhancement offered by SOI devices is limited in its scope.

Another new substrate material used in the art to enhance speed and reduce power is the use of mobility enhancement in devices created on a strained silicon substrate. To date, efforts have focused on circuits that employ a buried channel device for the P doped MOSFET (PMOS), and a surface channel device for the N doped MOSFET (NMOS). This arrangement provides the maximum mobility enhancement; however, there are limitations. At high fields, the buried channel PMOS device performance is complex due to the activation of two carrier channels, and therefore device circuit design, as well as the semiconductor process that makes these buried channel PMOS devices, becomes difficult.

In addition to this limitation, there is a further limitation that in order to create a buried channel PMOS device and surface channel NMOS device on the same strained silicon substrate, the cost of semiconductor fabrication required is significantly higher compared to that for bulk silicon processing.

It is first object of this invention to create a high speed, low power high density CMOS inverter comprising a surface channel PMOS and surface channel NMOS in a strained silicon substrate, where both PMOS and NMOS devices are on the same monolithic substrate to keep cost and complexity down.

It is another object of this invention to create strained silicon surface channel substrates that can be incorporated with SOI technology in order to provide ultra-high speed/low power circuits.

It is another object of this invention to create a strained silicon surface channel CMOS inverter circuit built on a bonded SiGe structure.

It is another object of this invention to create strained silicon surface channel devices that can be fabricated with standard silicon CMOS processing tools and semiconductor materials allowing for performance enhancement with no additional capital expenditures.

It is another object of this invention to create high speed or high frequency of operation CMOS inverter circuits using PMOS or NMOS strained silicon surface channel devices while keeping the power constant. This scenario is useful for applications such as desktop computers where the speed is more crucial than the power consumption.

It is another object of this invention to create a high speed or high frequency of operation CMOS inverter circuit on a strained silicon surface channel device while keeping the power constant. By judiciously swapping a strained silicon substrate for the bulk silicon substrate in the process, and taking into account the changes in process (implants etc.), certain circuit and design changes are made (supporting CMOS) to account for the increase in speeds for the CMOS inverter so that race conditions do not occur. This scenario is useful for applications such as desktop computers where the speed is more crucial than the power consumption.

It is another object of this invention to create even higher speed or higher frequency of operation CMOS inverter circuit while keeping the power constant by employing strained silicon improvements with constant V_{DD}. This scenario is useful for applications such as desktop computers where the speed is more crucial than the power consumption.

It is another object of this invention to create a reduced power CMOS inverter circuit used at constant speed or frequency of operation. This situation is most useful for portable applications that operate off of a limited power supply.

It is another object of this invention to create more dense inverters based upon PMOS or NMOS strained silicon surface channel devices.

It is another object of this invention to create a balanced operation CMOS inverter circuit.

It is another object of this invention to create a balanced operation CMOS inverter circuit with device capacitance being dominant over wiring capacitance.

It is another object of this invention to create a balanced operation CMOS inverter circuit with device capacitance being dominant over device capacitance.

It is another object of this invention to create a strained silicon surface channel CMOS inverter circuit for both long and short channel devices.

It is another object of this invention to create strained silicon surface channel devices that are scalable (shrinkable in dimensions) using the standard silicon substrate scaling tools (photolithography etc.) and materials. Thus scaling can be implemented in both long and short channel strained silicon surface devices.

It is another object of this invention to create strained silicon surface channel technology, which is similar to bulk silicon technology so that strained silicon channel devices can achieve all the other enhancement methods of bulk silicon technology, e.g. isolation, implantation, wiring, etc.

It is another object of this invention to use strained silicon surface channel CMOS circuits to build many basic digital circuits building blocks.

### SUMMARY OF THE INVENTION

In accordance with the invention, the performance of a silicon CMOS inverter is enhanced by increasing the electron and hole mobility. This enhancement is achieved through deploying surface channel, strained-silicon, which is epitaxially grown on an engineered SiGe/Si substrate. Both the n-type and p-type channels (NMOS and PMOS) are surface channel, enhancement mode devices. This technique allows the CMOS inverter performance to be improved (density, power, speed, or a combination thereof) without adding complexity to circuit fabrication or design.

### The Strained Silicon Substrate

When silicon is placed under tension, the degeneracy of the conduction band splits, forcing two valleys to be occupied instead of six. As a result, the in-plane, room temperature electron mobility is dramatically increased. Mobility enhancements can be incorporated into the basic MOSFET and basic CMOS inverter circuit in a number of ways as demonstrated by the many embodiments of this invention, but primarily through a semiconductor substrate material that allows for strained silicon surface channel PMOS and NMOS devices on the same common substrate materials. This strained silicon substrate allows for common semiconductor processing and semiconductor materials to be used.

In the basic strained silicon surface channel PMOS and NMOS structure, a compositionally graded SiGe buffer layer is used to accommodate the lattice mismatch between a relaxed SiGe layer and a Si substrate. By spreading the lattice mismatch over a distance, the SiGe graded buffer minimizes the number of dislocations reaching the surface and thus provides for a method of growing high-quality relaxed SiGe layers on a silicon substrate. After this, an epitaxially grown strained silicon layer is grown on the relaxed SiGe layer. Since the lattice constant of relaxed SiGe is larger than that of silicon, the strained silicon layer is under biaxial tension and thus the carriers exhibit strain-enhanced mobility.

Strained silicon surface channel devices can be fabricated with standard silicon CMOS processing tools and semiconductor materials. This compatibility allows for performance enhancement with no additional capital expenditures.

The strained silicon surface channel device technology is also scalable (shrinking size) using the standard silicon substrate based scaling tools (photolithography etc.) and materials (thinner gate oxide etc.). This scaling can be implemented for both long and short channel devices.

If desired, strained silicon surface channel substrates can be incorporated with SOI technology in order to provide ultra-high speed/low power circuits. Furthermore, strained silicon surface channel substrates can be incorporated with SiGe bonded wafers in order to provide ultra-high speed/low power circuits.

Since strained silicon surface channel technology is similar to bulk silicon technology, it can use other enhancement methods used for bulk silicon substrates (ion implantation, wiring etc.). As a result, strained silicon is an excellent technique for CMOS inverter circuit performance improvements.

### Performance Characteristics

There are two primary methods of extracting performance enhancement from the increased carrier mobility, allowed for by strained silicon surface channel inverter circuits.

In the first method, the frequency of operation can be increased while keeping the power constant. The propagation delay of a CMOS inverter is inversely proportional to the carrier mobility. Thus, if the carrier mobility is increased, as is the case with the strained silicon surface channel PMOS and NMOS CMOS inverter circuits, the propagation delay of the CMOS inverter circuit decreases, causing the overall CMOS inverter circuit speed to increase. This scenario is useful for applications such as desktop computers where the speed is more crucial than the power consumption.

In the second method, the power consumption can be decreased at a constant frequency of operation. When the carrier mobility increases, the gate voltage of the devices in the CMOS Inverter circuit can be reduced by an inverse amount while maintaining the same inverter speed of the CMOS inverter circuit. Since power is proportional to the square of the NMOS or PMOS device gate voltage of the CMOS inverter circuit, the reduction results in a significant decrease in the power consumption. This situation is most useful for portable applications that operate off of a limited power supply.

### BRIEF DESCRIPTION OF THE DRAWINGS

FIG. 1 is a cross-section of the strained silicon substrate structure with a typical strained silicon surface channel MOSFET;

FIGS. 2A and 2B are graphs of mobility enhancements vs. effective Field for electrons and holes, respectively, for strained silicon on Si₁₋ₓGeₓ for x=10-30%;

FIG. 3 is a table that displays surface roughness data for various relaxed SiGe buffers on Si substrates;

FIGS. 4A and 4B describes a schematic diagram of a CMOS inverter and its input and output voltage waveforms respectively;

FIGS. 5A-5C are schematic diagrams of the structures of a strained silicon MOSFET, a strained silicon MOSFET on SOI, and a strained silicon MOSFET on a bulk silicon substrate on bonded SiGe, respectively;

FIG. 6 is a table showing electron and hole mobility enhancements measured for strained silicon on 20% and 30% SiGe;

FIG. 7 is a table showing inverter characteristics for 1.2 μm CMOS fabricated in both bulk and strained silicon when the interconnect capacitance is dominant;

FIG. 8 is a table showing additional scenarios for strained silicon inverters when the interconnect capacitance is dominant;

FIG. 9 is a table showing inverter characteristics for 1.2 μm CMOS fabricated in both bulk and strained silicon when the device capacitance is dominant;

FIG. 10 is a graph showing NMOSFET transconductance versus channel length for various carrier mobilities;

FIG. 11 is a graph showing the propagation delay of a 0.25 μm CMOS inverter for a range of electron and hole mobility enhancements;

FIGS. 12A-12E show a fabrication process sequence for strained silicon on SOI substrates; and

FIGS. 13A-13C are circuit schematics for a NOR gate, a NAND gate and a XOR gate, respectively.

### DETAILED DESCRIPTION OF THE INVENTION

### Strained Silicon Surface Channel Devices

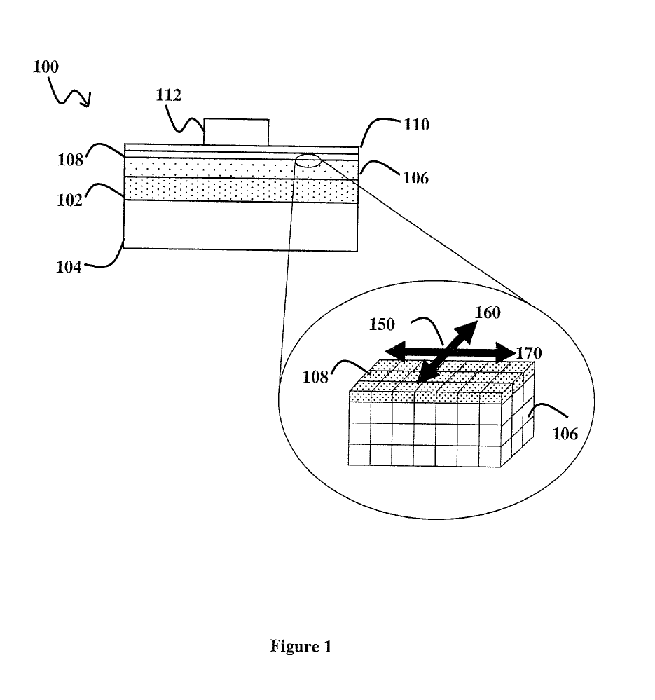

FIG. 1 is a cross-section of the substrate structure 100 required to produce a strained silicon surface channel MOSFET. Polysilicon gate 112 is on top of thin silicon dioxide (SiO2) dielectric material 110, which is on top of biaxial strained silicon surface layer 108, which is on top of relaxed SiGe layer 106, which is on top of graded SiGe layer 102, which is on top of bulk silicon substrate layer 104. These layers are deposited using known, standard semiconductor processes.

The larger lattice constant, relaxed SiGe layer 106 applies biaxial strain to the silicon surface layer 108. In this structure, a compositionally SiGe graded buffer layer 102 is used to accommodate the lattice mismatch between a relaxed SiGe layer 106 and a silicon substrate 104. By spreading the lattice mismatch over a thickness of the SiGe graded buffer 102, the SiGe graded 102 buffer minimizes the number of threading dislocations (a dislocation comprised of a “line of atoms” not “lined up” with the crystallographic structure and which can cause electrical leakage) reaching the next layer to be deposited, which is the relaxed SiGe layer 106. This SiGe graded buffer 102 provides a means for growing high quality relaxed SiGe layer 106 on silicon substrate 104.

Subsequently, a strained silicon surface layer 108 below the critical thickness (the thickness where it becomes energetically favorable to introduce dislocations) can be grown on the relaxed SiGe layer 106. Since the lattice constant of relaxed SiGe layer 106 is larger than that of the silicon substrate 104, the strained silicon surface layer 108 is under biaxial tension 150 (tension in both axes 160 and 170) and thus the carriers exhibit strain-enhanced mobility.

In the structure shown in FIG. 1, the strained silicon surface layer 108 is placed under biaxial tension by the underlying, larger lattice constant SiGe layer. From a solid state physics point of view, it is well known in the art that the strain of the silicon layer causes the conduction band of the silicon layer to split into two-fold and four-fold degenerate bands. The two-fold band is preferentially occupied since it sits at a lower energy state. The energy separation between the bands is approximately

ΔEₛₜᵣₐᵢₙ=0.67·x(eV) (1)

where x is equal to the Ge content in the SiGe layer. The equation shows that the band splitting increases as the Ge content increases. This splitting causes mobility enhancement by two mechanisms. First, the two-fold band has a lower effective mass, and thus higher mobility than the four-fold band. Therefore, as the higher mobility band becomes energetically preferred, the average carrier mobility increases. Second, since the carriers are occupying two orbitals instead of six, and therefore inter-valley phonon scattering is reduced, further enhancing the carrier mobility.

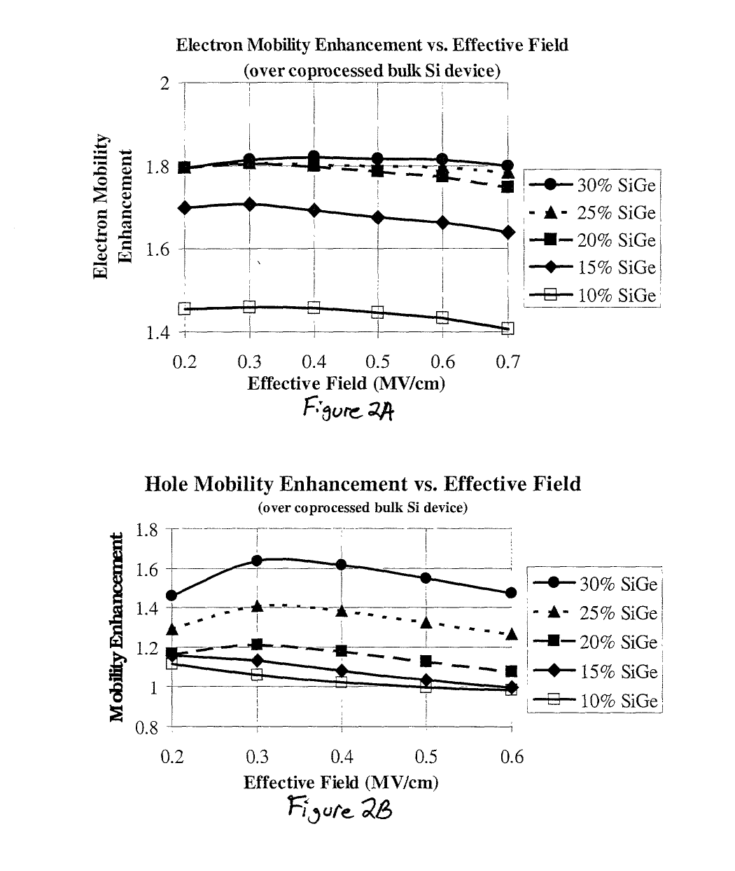

The effects of germanium (Ge) concentration (amount of germanium in silicon) of the Ge in the relaxed SiGe layer 106 in FIG. 1, on the electron and hole mobility of the surface channel silicon devices can be seen in FIGS. 2A and 2B respectively. FIGS. 2A and 2B are graphs of mobility enhancements versus effective fields in megavolts per centimeter for electrons and holes, respectively, for strained silicon on Si₁₋ₓGeₓ, for x=10-30%. At 20% Ge, the electron enhancement at high fields is approximately 1.75 (relative to bulk silicon) while the hole enhancement is essentially negligible. Above approximately 20% Ge, the electron enhancement saturates (no longer increases for increased Ge concentrations). This saturation occurs because the conduction band splitting is large enough that almost all of the electrons occupy the high mobility band. As shown in FIG. 2B, hole enhancement saturation has not yet been observed; therefore, raising the Ge concentration to 30% increases hole mobility by a factor of 1.4. Hole enhancement saturation is predicted to occur at a Ge concentration of about 40%. The ability to add more Ge to increase the hole mobility without further increases in electron mobility will become useful in designing surface channel CMOS inverter designs.

Researchers have found that at significant increases in percent Ge content in the SiGe layer, the surface roughness of the SiGe layer increases and becomes problematic (e.g., it is hard to do submicron photolithography on it). Because of this, researchers have chosen to use low percentages of Ge in the SiGe layer so that surface roughness effects are minimized and thus see only the benefit of the electron mobility. In this case, researchers do not see the enhancement of hole mobility achieved at higher percentages of Ge. The low hole mobility in surface channel devices has caused other researchers to move to higher mobility, buried channel devices for the PMOSFETs.

Until recently, the material quality of relaxed SiGe on Si was insufficient for utilization in CMOS fabrication. During epitaxial growth, the surface of the SiGe becomes very rough and creates crosshatched patterns on the surface of the SiGe layer, which causes further problems with subsequent photolithography as well as device degradation since the gate oxide is grown on this surface. This roughness is caused because the SiGe material on Si is relaxed via dislocation introduction. Researchers have tried to control the surface morphology through the growth process. However, since the stress fields from the misfit dislocations affect the growth front, no intrinsic epitaxial solution is possible. U.S. Pat. No. 6,107,653 issued to Fitzgerald, incorporated herein by reference, describes a method of planarization and regrowth that allows all devices on relaxed SiGe to possess a significantly flatter surface. This reduction in surface roughness is critical in the production of strained Si CMOS devices since it increases the yield for fine-line lithography.

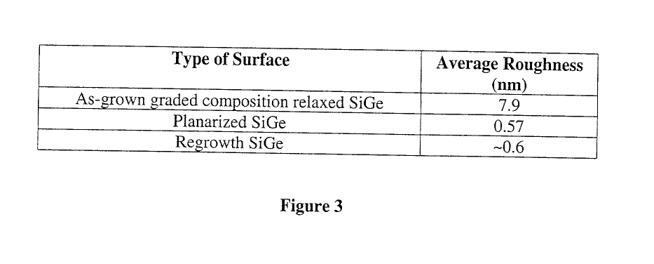

FIG. 3 is a table that displays surface roughness data for various relaxed SiGe buffers on Si substrates. It will be appreciated that the as-grown crosshatch pattern for relaxed Si_{0.8}Ge_{0.2} buffers creates a typical roughness of approximately 7.9 nm. This average roughness increases as the Ge content in the relaxed buffer is increased. Thus, for any relaxed SiGe layer that is relaxed through dislocation introduction during growth, the surface roughness is unacceptable for state-of-the-art photolithography. After the relaxed SiGe is planarized, the average roughness is less than 1 nm (typically 0.57 nm), and after a 1.5 μm silicon device layer epitaxial grown layer is completed, the average roughness is 0.77 nm. Therefore, after the complete structure is fabricated, there is over an order of magnitude reduction in the surface roughness. The resulting high quality material is well suited for state of the art CMOS photolithographic processing.

It is shown that because of the planarized SiGe layer, we can use higher Ge percentages so that the strained silicon provides significant CMOS enhancement since both high electron and high hole mobility can be achieved using surface channel devices for both NMOS and PMOS respectively without the need for a buried channel. This design allows for high performance without the complications of adding a buried channel device to obtain dual channel operation and without adding complexity to circuit fabrication (surface and buried channel devices on the same substrate).

### CMOS Inverter

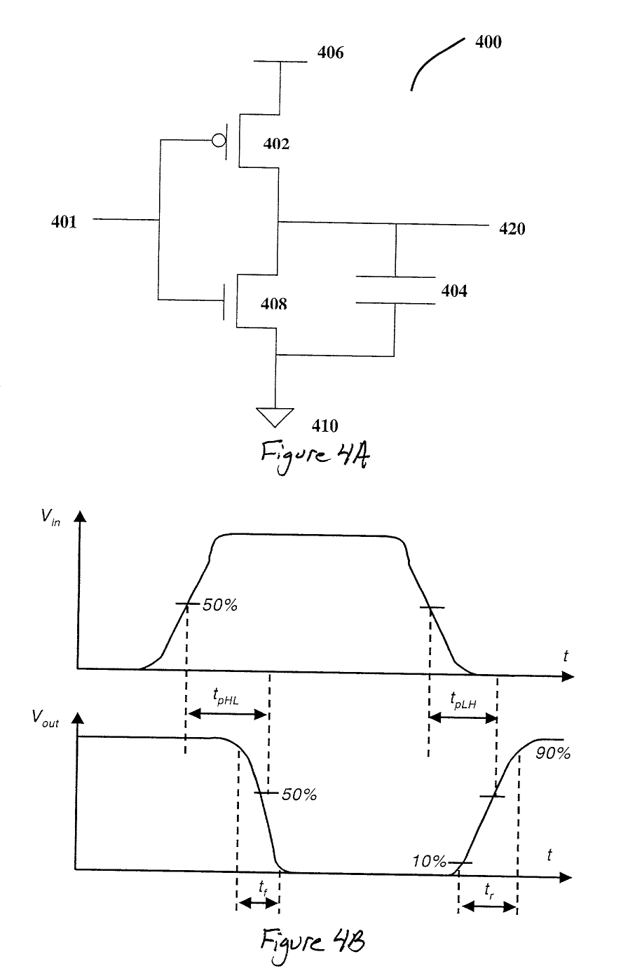

FIG. 4A is a schematic diagram of a CMOS inverter 400. When the input voltage, 401 or V_{in,} to the inverter is low, a PMOS transistor 402 turns on, charges up a load capacitance 404, and the output 420 goes to a gate drive 406, V_{DD}. Alternatively, when 401 Vᵢₙ is high, an NMOS transistor 408 turns on, and discharges the load capacitance 404, and the output node goes to ground level 410. In this manner, the inverter is able to perform the logic swing necessary for digital processing.

The propagation delay of the CMOS inverter is determined by the time it takes to charge and discharge the load capacitance 404 or C_{L} through PMOS 402 and NMOS 408 transistors, respectively. The load capacitance, denoted as 404 or C_{L}, represents a lumped model of all of the capacitances between Vₒᵤₜ 420 and ground 410.

### Lumped Capacitance

The following equation defines the Lumped Capacitance:

C_{L}=(C_{dp1}+C_{dn1})+(C_{gp2}+C_{gn2})+C_{W} (2)

where C_{dp1} and C_{dn1} are the equivalent drain diffusions capacitances of PMOS 402 and NMOS 408 transistors, respectively, of the first inverter, while C_{gp2} and C_{gn2} are the gate capacitances of the an attached second gate inverter (not shown). C_{w} represents the wiring capacitance. This is explained by reference #1 to Chapter 3 of Digital Integrated Circuits by Jan Rabaey, Prentice Hall Electronics and VLSI series, copyright 1996.

### Time Constant

FIG. 4B shows the propagation delay ofthe CMOS inverter of FIG. 4B. The gate defines how quickly it responds to a change at its input and relates directly to the speed and performance metrics. The propagation delay expresses the delay experienced by a signal passing through the gate. It is measured between the 50% transition points of the input and output waveforms, as shown in FIG. 4A for the inverting gate. Because the gate displays different response times for rising or falling input waveforms, two definitions of the propagation delay are necessary. The t_{pLH} defines the response time of the gate for a low to high (or positive) output transition, while t_{pHL} refers to a high to low (or negative) transition. The overall propagation delay is defined as the average of the two:

$${t}_{p} = \frac{{t}_{pHL} + {t}_{pLH}}{2} \qquad ( 3 )$$

Since the load capacitance must be fully charged or discharged before the logic swing is complete, the magnitude of C_{L} has a large impact on inverter performance. The performance is usually quantified by two variables: the propagation delay, tₚ, and the power consumed, P. The propagation delay is defined as how quickly a gate responds to a change in its input and can also be given by:

$${t}_{p} = \frac{{C}_{L} \cdot {V}_{DD}}{{I}_{av}} \qquad ( 4 )$$

where Iₐᵥ is the average current during the voltage transition. There is a propagation delay term associated with the NMOS discharging current, t_{pHL}, and a term associated with the PMOS charging current, t_{pLH}. The average of these two values (as before) represents the overall inverter delay:

$${t}_{p} = \frac{{t}_{pHL} + {t}_{pLH}}{2} \qquad ( 4 )$$

### Power

Assuming that static and short-circuit power are negligible, the power consumed can be written as

$$P = \frac{{C}_{L} \cdot {V}_{DD}^{2}}{{t}_{p}} \qquad ( 5 )$$

From equations above, one can see that both the propagation delay and the power consumption have a linear dependence on the load capacitance. In an inverter, C_{L} consists of two major components: wiring capacitance and device capacitance. Which component dominates C_{L} depends on the architecture of the circuit in question.

### Mobility—μₙ or μₚ

The electron velocity is related to the electric field through a parameter called the mobility ofthe M material (μₙ)or the mobility of the P material (μₚ) (expressed in cm²/V-sec). The mobility is a complex function of the crystal structure. The higher the mobility, the greater the electron velocity.

### Gain factor—kₙ or kₚ

According to reference #1, the gain factor is a product of process transconductance and the dimensions width/length (W/L) of the transistor. The propagation delay of a gate can be minimized by increasing kₙ or kₚ, or equivalently, increase the W/L ratio of the transistors. This might seem a straightforward and desirable solution. However, a word of caution is necessary. Increasing the W/L ratio (transistor size) also increases the diffusion capacitance (and C_{L}) as well as the gate capacitance. An equation for gain factor is shown below:

$${K}_{n} = {μ}_{n} {C}_{ox} \times \frac{{μ}_{n}}{{L}_{n}} \qquad ( 6 )$$

where Cₒₓ is the capacitance of the thin oxide gate capacitance.

### Derivation of relationship between tₚ,μ, and W/L

In order to understand the inverter performance of propagation delay (tₚ) and power (P), it is necessary to derive tₚ and P in terms of μₙ, μₚ, W, L, and Cₗ, so that we can see the effects of these design parameters. From reference #1, it is known that:

$${t}_{p} = \frac{{C}_{L}}{2 {V}_{DD} {K}_{n}} ( 1 + \frac{{μ}_{n}}{{μ}_{p}} ( \frac{{W}_{n}}{{L}_{n}} ) \frac{{L}_{p}}{{W}_{p}} ) \qquad ( 7 )$$

where V_{DD} is the gate drive voltage.

Substituting gain factor as shown in equation 6,

$${t}_{p} = \frac{{C}_{L}}{2 {V}_{DD} {μ}_{n} {C}_{ox}} \times \frac{{L}_{n}}{{W}_{n}} ( 1 + \frac{{μ}_{n}}{{μ}_{p}} ( \frac{{W}_{n}}{{L}_{n}} ) \frac{{L}_{p}}{{W}_{p}} ) \qquad ( 8 )$$

therefore:

$${t}_{p} = \frac{{C}_{L}}{2 {V}_{DD} {μ}_{n} {C}_{ox}} ( \frac{{L}_{n}}{{W}_{n}} + \frac{{μ}_{n}}{{μ}_{p}} \times \frac{{L}_{p}}{{W}_{p}} ) \qquad ( 9 )$$

and further,

$${t}_{p} = \frac{{C}_{L}}{2 {V}_{DD} {C}_{ox}} ( \frac{{L}_{n}}{{μ}_{n} {W}_{n}} + \frac{{L}_{p}}{{μ}_{p} {W}_{p}} ) \qquad ( 10 )$$

therefore from equation 7, the following relationships can be defined:

$${t}_{p} ∝ {C}_{L} ∝ \frac{1}{{μ}_{n}} ∝ \frac{1}{{μ}_{p}} ∝ \frac{1}{{W}_{n}} ∝ \frac{1}{{W}_{p}} \qquad ( 11 )$$

### Derivation of relationship between P and W/L

Assuming that static and short-circuit power are negligible, the power equation (5) and (11) above we know tₚ is inversely proportional to W. Therefore it is derived that:

P∝W (12)

which means that as width decreases, so does the power of the circuit.

### First Embodiment: Basic Surface Channel PMOS and NMOS Strained Silicon Devices Forming an Inverter Circuit

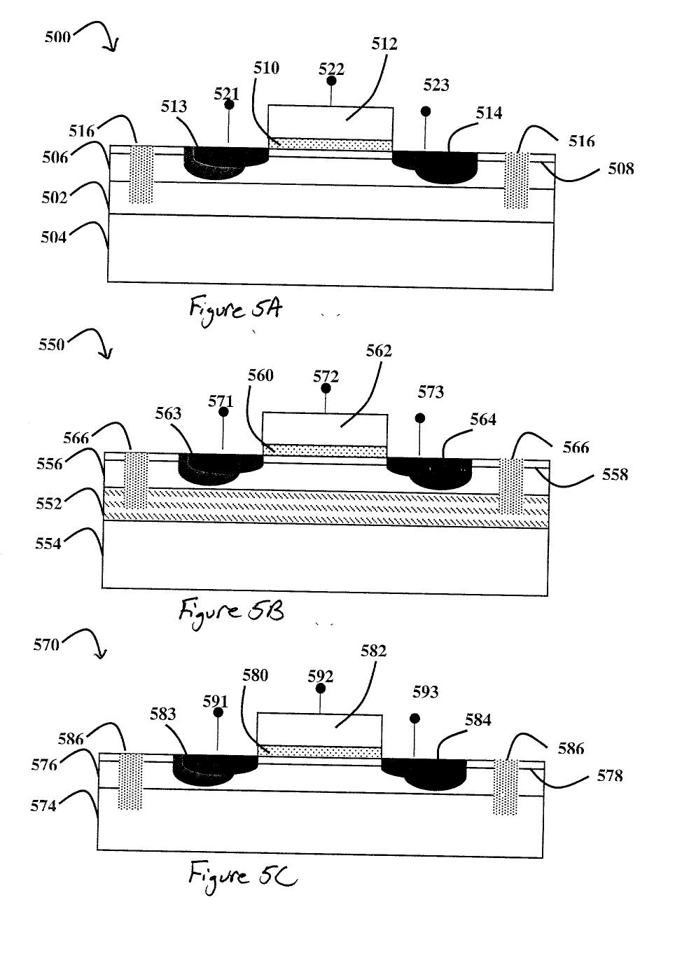

FIGS. 5A is a basic schematic diagram of the MOSFET device structures of a strained silicon MOSFET 500 on a bulk silicon substrate. The structure in FIG. 5A contains silicon substrate 504, with a layer of a SiGe graded buffer 502 grown on it, which in turn has a relaxed SiGe layer 506 grown on it, which in turn has a strained silicon layer 508 grown on it. These layers are grown through standard semiconductor epitaxial processing. As would be standard to semiconductor processing, the MOSFET and the isolation regions are also defined. These are shown in FIG. 5A as shallow trench isolations regions 516, gate oxide region 510, polysilicon gate region 512, and lightly doped drain region 514 and lightly doped source region 513. These are the basic regions of a MOSFET device. It should be noted that this device can be defined as either an N-type channel or P-type channel through appropriate and well-understood semiconductor ion implantation of dopants as well as their subsequent anneals. Also shown in FIG. 5A are the thicknesses of graded SiGe layers 502 (typically 1-5 microns), relaxed SiGe layer 506 (typically 0.1-2 microns), strained silicon layer 508 (typically less than 300 angstroms or approximately equal to or less than the critical thickness), and gate oxide 510 (typically 100 angstroms). Also shown in FIG. 5A are source connection 521, gate connection 522 and drain connection 523. It should be noted that planarization of the SiGe layers may be required to reduce surface roughness.

In the MOSFET structure in FIG. 5A, the strained Si layer 508 serves as the carrier channel, thus enabling improved device performance over their bulk Si counterparts.

Once the NMOS and PMOS are defined in the semiconductor process (using standard techniques known in the art), the wiring connections of the NMOS and PMOS devices are connected as shown in the inverter circuit of FIG. 4A. Thus a strained silicon surface channel inverter is formed, allowing the benefits of high percent Ge and hence both high electron and high hole mobility.

### Second Embodiment: Basic Surface Channel PMOS and NMOS Strained Silicon Devices Forming an Inverter Circuit Using Bonded SOI

FIG. 5B is a basic schematic diagram of the MOSFET device structures of a strained silicon MOSFET 550 on a bulk silicon substrate on Silicon On Insulator (SOI). The structure in FIG. 5B contains silicon substrate 554, with a layer of a SOI 552 bonded to it. This bonded SOI was previously formed with a relaxed SiGe layer 556 grown on it, which in turn has a strained silicon layer 558 grown on it. These layers on the SOI are grown through standard semiconductor epitaxial processing. The MOSFET and the isolation regions are also defined according to standard semiconductor processing. These basic regions of a MOSFET device are shown in FIG. 5B as shallow trench isolations regions 566, gate oxide region 560, polysilicon gate region 562, and lightly doped drain region 564 and lightly doped source region 563. It should be noted that this device can be defined as either an N-type channel or P-type channel through appropriate and well-understood semiconductor ion implantation of dopants as well as their subsequent anneals. Also shown in FIG. 5B are source connection 571, gate connection 572 and drain connection 573. In the MOSFET structure in FIG. 5B, the strained Si layer 558 serves as the carrier channel, thus enabling improved device performance over their bulk Si counterparts.

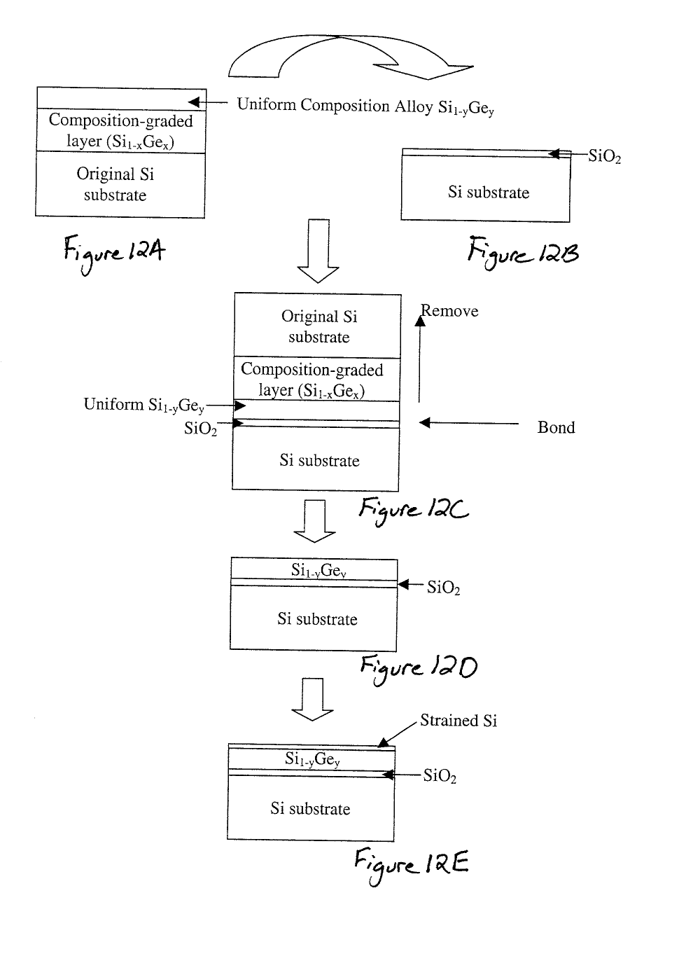

Strained silicon technology can also be incorporated with SOI technology for added performance benefits. FIGS. 12A-12E show a fabrication process sequence for strained silicon on SOI substrates. First, a SiGe graded buffer layer 1202 is grown on a silicon substrate 1200 with a uniform relaxed SiGe cap layer 1204 of the desired concentration (FIG. 12A). This wafer is then bonded to a silicon wafer 1206 oxidized with a SiO₂ layer 1208 (FIGS. 12B-12C). The initial substrate and graded layer are then removed through either wafer thinning or delamination methods. The resulting structure is a fully relaxed SiGe layer on oxide (FIG. 12D). A strained silicon layer 1210 can subsequently be grown on the engineered substrate to provide a platform for strained silicon, SOI devices (FIG. 12E). The resulting circuits would experience the performance enhancement of strained silicon as well as about an 18% performance improvement from the SOI architecture. In short channel devices, this improvement is equivalent to 3-4 scaling generations at a constant gate length.

Once the NMOS and PMOS are defined in the semiconductor process (using standard techniques known in the art), the wiring connections of the NMOS and PMOS devices are connected as shown in the inverter circuit of FIG. 4A. Thus a strained silicon surface channel inverter is formed, allowing the benefits of high percent Ge and hence both high electron and high hole mobility.

### Third Embodiment: Basic Surface Channel PMOS and NMOS Strained Silicon Devices Forming an Inverter Circuit Using Bonded SiGe

FIGS. 5C is a basic schematic diagram of the MOSFET device structures of a strained silicon MOSFET 570 on a bulk silicon substrate on bonded SiGe. The structure in FIG. 5C contains a silicon substrate 574. A relaxed SiGe layer 576 is bonded to substrate 574. On top of this relaxed SiGe 576 layer is a strained silicon layer 578, which in turn has a layer of SiO2 580 on top of it. On top of SiO2 580 is polysilicon gate region 582. The MOSFET and the isolation regions are also defined according to standard semiconductor processing. These basic regions of a MOSFET device are shown in FIG. 5C as shallow trench isolations regions 586, gate oxide region 580, polysilicon gate region 582, and lightly doped drain region 584 and lightly doped source region 583. It should be noted that this device can be defined as either an N-type channel or P-type channel through appropriate and well-understood semiconductor ion implantation of dopants as well as their subsequent anneals. Also shown in FIG. 5C are source connection 591, gate connection 592 and drain connection 593.

A similar fabrication method can be used to provide relaxed SiGe layers directly on Si, i.e., without the presence of the graded buffer or an intermediate oxide. This heterostructure is a fabricated using the sequence shown in FIGS. 12A-12D without the oxide layer on the Si substrate. The graded composition layer possesses many dislocations and is quite thick relative to other epitaxial layers and to typical step-heights in CMOS. In addition, SiGe does not transfer heat as rapidly as Si. Therefore, a relaxed SiGe layer directly on Si is well suited for high power applications since the heat can be conducted away from the SiGe layer more efficiently.

Once the NMOS and PMOS are defined in the semiconductor process using standard techniques known in the art, the wiring connects the NMOS and PMOS device together as an inverter as shown in FIG. 4A. Thus a strained silicon surface channel inverter is formed.

### Fourth Embodiment: PMOS and NMOS Surface Channel Strained Silicon Devices Forming an Inverter Circuit with Optimnized SiGe Ratios of the Relaxed SiGe Layer for Enhanced Speed with Lower V_{DD}, Constant Power and Device Capacitance Much Greater than Wiring Capacitance.

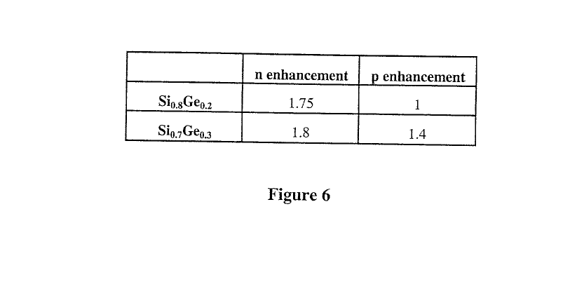

Whether the basic inverter devices are built on bulk silicon as in FIG. 5A or on bonded SOI as in FIG. 5B, or on bonded SiGe as in FIG. 5C, the Ge percentage used in the relaxed SiGe can be modified to create the strained silicon layer, circuit speed, or circuit power effects. When strained silicon is used as the carrier channel, the electron and hole mobilities are multiplied by enhancement factors. As discussed before in FIGS. 2A and 2B, the enhancement differs for electrons and holes and also varies with the Ge fraction in the underlying SiGe layer. A summary of the enhancements for Si_{0.8}Ge_{0.2} and Si_{0.7}Ge_{0.3} is shown in FIG. 6. FIG. 6 is a table showing electron and hole mobility enhancements measured for strained silicon on 20% and 30% SiGe. As will be shown by both derivations from first principles and by calculations in a MatLab™ analysis tool, we can enhance the speed of a basic inverter by using relaxed SiGe and more importantly, with addition of the right amount of Ge in the relaxed SiGe layer, the strained silicon layer on top of this layer will produce optimized inverter speeds over bulk silicon surface channel devices commonly used in inverters today.

If we consider the mobility of the NMOS and PMOS for bulk silicon devices (μₙ or μₚ) to be a reference of unity (1), then the use of strained silicon on relaxed SiGe as described in FIG. 6 (using the enhancement factor for each device) demonstrates mobility μₙ=1.75, μₚ=1 for 20% Ge in relaxed SiGe; or mobility μₙ=1.8, μₚ=1.4 for 30% Ge in relaxed SiGe. Both μₙ and μₚ are both increased for 30% Ge and only μₙ is enhanced for 20% Ge.

From equation 10, which is derived from first principles of an inverter for MOSFETs:

$${t}_{p} = \frac{{C}_{L}}{2 {V}_{DD} {C}_{ox}} ( \frac{{L}_{n}}{{μ}_{n} {W}_{n}} + \frac{{L}_{p}}{{μ}_{p} {W}_{p}} ) \qquad ( 10 )$$

if we hold constant the device size(Wₙ, Wₚ, Lₙ, Lₚ) for bulk silicon to be the same as for our strained silicon, it can be seen that when either μ_{n or} μₚ go up, the tₚ goes down and hence the inverter gets faster.

These enhancements are shown using results from a MatLab™ analysis tool where these parameters are programmed to calculate more exacting results. We have chosen a nominal design point of sizes of the basic devices of an inverter to demonstrate the enhancement of speed. We have incorporated a ground rule of a 1.2 μm CMOS model in order to quantify the effects on inverter performance. The analysis minimized the wiring capacitance so that Cw was much less than the lumped device capacitance of equation (2), so only device effects were investigated.

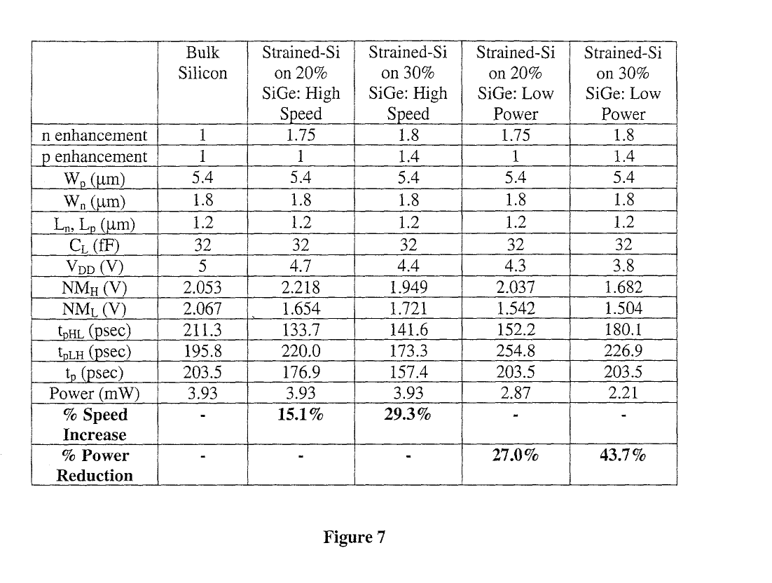

The values for a bulk silicon, 1.2 μm symmetrical inverter are calculated and are shown in FIG. 7. In this set of calculations, the device capacitance is much greater than the wiring capacitance. FIG. 7 is a table showing inverter characteristics for 1.2 μm CMOS fabricated in both bulk and strained silicon. The propagation delay for the bulk silicon inverter is tₚ₌203.5 picoseconds and the consumed power is 3.93 mW. In an application where speed is paramount, such as in desktop computing, strained silicon provides a good way to enhance the circuit speed. Assuming no change from the bulk silicon design, a strained silicon inverter on Si_{0.8}Ge_{0.2} results in a 15.1% speed increase over the bulk silicon base case at constant power. When the channel is on Si_{0.7}Ge_{0.3}, the speed enhancement improves to 29.3% over the bulk silicon base case (FIG. 7).

If there is no change from the bulk silicon design, a PMOS and NMOS surface channel strained silicon inverter circuit will achieve higher speeds over the bulk silicon. If strained silicon were simply swapped in the process for the substrate, outside of taking into account the changes needed in processing to ensure the implants and other processes created the same inverter, attached circuits may have to be modified to eliminate race conditions that may occur. That is, if inverters were sped up, the circuits that attach to these inverters may have to be modified in terms of changes there lengths or widths to account for the enhanced speeds. Note that V_{DD} was reduced to maintain a constant power.

### Fifth Embodiment: PMOS and NMOS Surface Channel Strained Silicon Devices Forming an Inverter Circuit with optimized SiGe ratios of the Relaxed SiGe layer for enhanced Speed by maintaining V_{DD} for Wiring Capacitance Much Greater Than Device Capacitance

In advanced ground rule designs, wiring limitations force designers to pack wires in much greater density and even at times create “borderless contacts” (where the diffusion contact overlaps but is insulated from the gate) between the source diffusion region or drain diffusion region and the gate. When this and other wiring enhancements are made, wiring capacitance becomes dominant over device capacitance.

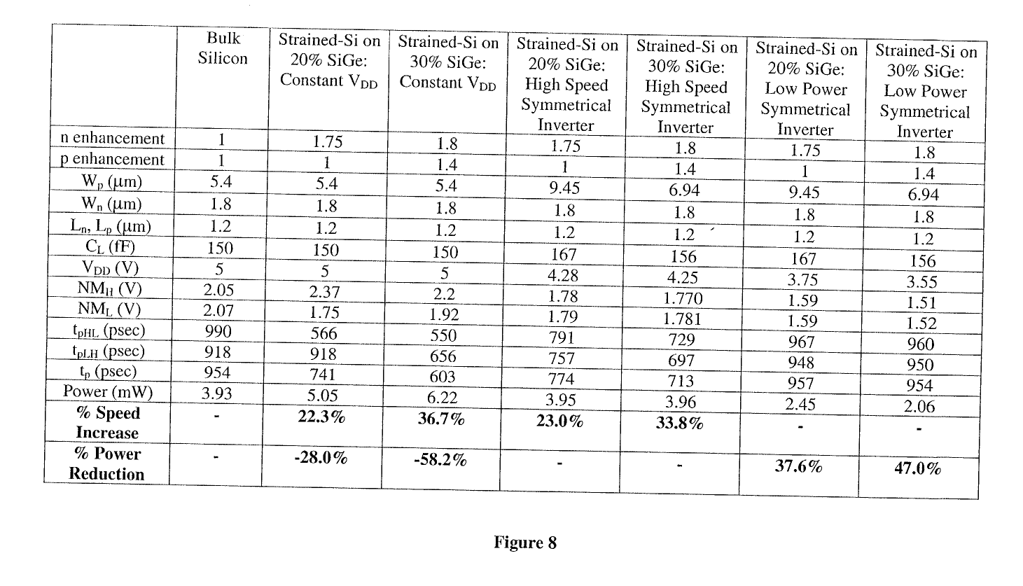

As described in the fourth embodiment above, a fuirther enhancement is found by maintaining V_{DD} for wiring capacitance-dominated designs. As shown in, FIG. 8 (where the wiring capacitance is much greater than device capacitance) and when V_{DD} is held constant (5 volts) at the same amount over the bulk silicon base case, the enhancement of speed increases to 22.3% over the bulk silicon base case and 36.7%, for Si on Si_{0.8}Ge_{0.2} and Si_{0.7}Ge_{0.3}, respectively. Note that in both these cases more power is required to achieve this speed (−28.0% and −58.2% power reduction over the bulk silicon base case, respectively).

### Sixth Embodiment: PMOS and NMOS Surface Channel Strained Silicon Devices Forming an Inverter Circuit with optimized SiGe ratios of the Relaxed SiGe Layer for Enhanced Power by Reducing V_{DD} for Device Capacitance Dominated Circuits.

As will be shown by both derivations from first principles and by calculations in a MatLab™ analysis tool, we can enhance the power of a basic inverter circuit by using a strained silicon surface channel for both PMOS and NMOS and more importantly, with the addition of the right amount of Ge in the relaxed SiGe layer, the strained silicon layer on top of this layer will produce optimized inverter power over bulk silicon surface channel devices used in inverters today.

If we consider the mobility of the NMOS and PMOS for bulk silicon devices (μₙ or μₚ) to be a reference of unity or 1, then the use of strained silicon on relaxed SiGe as described in FIG. 6 (using the enhancement factor for each device) demonstrates mobility μₙ=1.75, μₚ=1 for bulk silicon for 20% Ge in relaxed SiGe; or mobility ∞ₙ=1.8, μₚ=1.4 for that of bulk silicon for 30% Ge in relaxed SiGe. Both μₙ and μₚ are both increased for 30% Ge and only μₙ is enhanced for 20% Ge.

From equation 10, which is derived from first principles of an inverter for MOSFETs:

$${t}_{p} = \frac{{C}_{L}}{2 {V}_{DD} {C}_{ox}} ( \frac{{L}_{n}}{{μ}_{n} {W}_{n}} + \frac{{L}_{p}}{{μ}_{p} {W}_{p}} ) \qquad ( 10 )$$

if we hold constant the device size(Wₙ, Wₚ, Lₙ, Lₚ) for bulk silicon to be the same as for our strained silicon, it can be seen that when either μ_{n or}μₚ go up, the tₚ goes down and hence the in the inverter gets faster.

Also, from equation (5) before, we can see that:

$$P = \frac{{C}_{L} \cdot {V}_{DD}^{2}}{{t}_{p}} \qquad ( 5 )$$

Power can be enhanced by the square of V_{DD} (which is the drain voltage of the inverter) as well as a decrease in t_{p.} So by adding strained silicon the power goes up since tₚ goes down and when can decrease V_{DD} to further reduce power. Because we have used strained silicon as a substrate we can actually reduce V_{DD} to reduce power while maintaining the speed.

As shown in FIG. 7, by reducing the gate drive, V_{DD}, the power is reduced at a constant speed. For 20% SiGe, the power consumption is 27% lower than its bulk silicon counterpart. When 30% SiGe is used, the power is reduced by 43.7% from the bulk silicon value. This power reduction is important for portable computing applications such as laptops and handhelds.

### Seventh Embodiment: PMOS and NMOS Surface Channel Strained Silicon Devices Forming an Inverter Circuit With Optimized SiGe Ratios Of The Relaxed SiGe Layer For Enhanced Density.

As will be shown by derivations from first principles, we can reduce the density or size of an inverter circuit and maintain power and speed by using relaxed SiGe and more importantly, with addition of the right amount of Ge in the relaxed SiGe layer, the strained silicon layer on top of this layer will produce optimized inverter density over the bulk silicon surface channel devices used in inverters today.

If we consider the mobility of the NMOS and PMOS for bulk silicon devices (μₙ or μₚ) to be a reference of unity or 1, then the use of strained silicon on relaxed SiGe or mobility ratio as shown in FIG. 6 (using the enhancement factor for each device) demonstrates mobility μₙ=1.75 and μₚ=1 for 20% Ge in relaxed SiGe; or mobility μₙ=1.8 and μₚ=1.4 for 30% Ge in relaxed SiGe. Both μₙ and μₚ are both increased for 30% Ge and only μₙ is enhanced for 20% Ge.

From equation 10, which is derived from first principles of an inverter for MOSFET's,

$${t}_{p} = \frac{{C}_{L}}{2 {V}_{DD} {C}_{ox}} ( \frac{{L}_{n}}{{μ}_{n} {W}_{n}} + \frac{{L}_{p}}{{μ}_{p} {W}_{p}} ) \qquad ( 10 )$$

Since both μₙ and μₚ (or at least μₙ) goes up, we see that tₚ goes down for a faster inverter. We can raise the tₚ back up to where it may be for bulk silicon, by reducing Wₙ and Wₚ, in other words, we can reduce Wₙ and Wₚ by the factor that μₙ and μₚ increased so that the μₙWₙ and μₚWₚ factor remains constant. Thus, for the same speed tₚ, PMOS and NMOS strained silicon surface channel devices in an inverter circuit allows us to reduce the size of the inverter, everything else being held constant.

### Eighth Embodiment: PMOS and NMOS Surface Channel Strained Silicon Devices in a Symmetric Inverter Circuit with Optimized SiGe Ratios of the Relaxed SiGe Where Wiring Capacitance Dominant Circuits.

One drawback of strained silicon, surface channel CMOS is that the electron and hole mobility's are unbalanced further by the uneven electron and hole enhancements. This unbalance in mobility translates to an unbalance in the noise margins of the inverter. The noise margin represents the levels of noise that can be sustained when the gates are cascaded. A measure of the sensitivity of a gate to noise is given by the noise margin NM_{L} (noise margin low) and NM_{H} (noise margin high) which quantize the legal “0” and “1” of digital circuits. (Further explanation of these noise margins can be found in reference #1, Chapter 3 of Digital Integrated Circuits by Jan Rabaey, Prentice Hall Electronics and VLSI series, copyright 1996.) The noise margins represent the allowable variability in the high and low inputs to the inverter.

In bulk advanced ground rules where wiring capacitance is dominant, both the low and high noise margins are unbalanced for strained silicon at either 20% or 30% SiGe. For example, non-symmetric circuit (NM_{L}) in FIG. 8 shows that the high noise margin, NM_{H} for 20% Ge is 2.37 volts when the low noise margin is 1.75 volts. Also shown is non-symmetric circuit in FIG. 8 for 30% Ge. In this case, the high noise margin is 2.2 volts and the low noise margin is 1.92 volts.

However, if a symmetrical inverter is required, the PMOS device width must be increased to μₙ/μₚ times the NMOS device width. This translates to a 75% increase in PMOS width (1.75×5.4=9.45) for Si_{0.8}Ge_{0.2}, and a 29% increase (1.29×5.4=6.94) over the bulk silicon base case for Si_{0.7}Ge_{0.3}. If the increased area is acceptable for the intended application, inverter performance can be further enhanced. As shown in FIG. 8, in the constant power scenario, the speed can now be increased by 23.0% for Si_{0.8}Ge_{0.2} and by 33.8% for Si_{0.7}Ge_{0.3} for a symmetric inverter over the bulk silicon base case. When the power is reduced for a constant frequency, a 37.6% and 47.0% reduction in consumed power is possible with 20% and 30% SiGe, respectively (FIG. 8). However, in many applications an increase in device area is not tolerable. In these situations, if inverter symmetry is required, it is best to use strained silicon of 30% SiGe. Since the electron and hole enhancement is comparable on Si_{0.7}Ge_{0.3}, it is easier to trade off size for symmetry to meet the needs of the application.

### Ninth Embodiment: PMOS and NMOS Surface Channel Strained Silicon Devices in a Optimized Design Inverter with Optimized SiGe Ratios of the Relaxed SiGe and Dominated by Device Capacitance.

The device capacitance is dominant over the wiring capacitance in many analog applications. The device capacitance includes the diffusion and gate capacitance of the inverter itself as well as all inverters connected to the gate output, known as the fan-out. Since the capacitance of a device depends on its area, PMOS upsizing results in an increase in C_{L}. If inverter symmetry is not a prime concern, reducing the PMOS device size can increase the inverter speed. This PMOS downsizing has a negative effect on t_{pLH} but has a positive effect on t_{pHL}. The optimum speed is achieved when the ratio between PMOS and NMOS widths is set to \sqrt{μₙ/μₚ}, where μₙ and μₚ represent the electron and hole mobility, respectively.

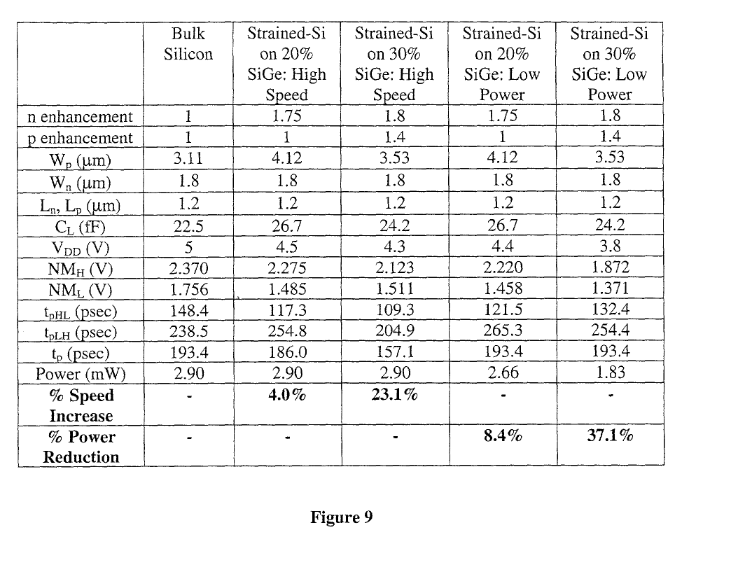

FIG. 9 is a table showing inverter characteristics for 1.2 μm CMOS fabricated in both bulk and strained silicon when the device capacitance is dominant. The strained silicon inverters are optimized to provide high speed at constant power and low power at constant speed. For strained silicon on Si_{0.8}Ge_{0.2}, the electron mobility is higher than the hole mobility. When the PMOS width is re-optimized by adjusting Wₚ and V_{DD} to accommodate these mobilities, i.e., by using the \sqrt{μₙ/μₚ} optimization (see Reference #1), the strained silicon PMOS device on Si_{0.8}Ge_{0.2} is over 30% wider ((4.12-3.11)/3.11) than the bulk Si PMOS device. The resulting increase in capacitance offsets some of the advantages of the enhanced mobility. Therefore, only a 4% speed increase occurs at constant power, and only an 8% decrease in power occurs at constant speed over the bulk silicon base case.

Although these improvements are significant, they represent a fraction of the performance improvement seen with a generation of scaling and do not surpass the performance capabilities available with SOI architectures.

In contrast, strained silicon on Si_{0.7}Ge_{0.3} offers a significant performance enhancement at constant gate length for circuits designed to the \sqrt{μₙ/μₚ} optimization. Since the electron and hole mobilities are more balanced, the effect on the load capacitance is less substantial. As a result, large performance gains can be achieved. At constant power, the inverter speed can be increased by over 23% and at constant speed, the power can be reduced by over 37% over the bulk silicon base case. The latter enhancement has large implications for portable analog applications such as wireless communications.

As in the microprocessor case (wiring or interconnect capacitance dominated), the strained silicon devices suffer from small low noise margins. Once again, this effect can be minimized by using 30% SiGe. If larger margins are required, the PMOS device width can be increased to provide the required symmetry. However, this PMOS upsizing increases C_{L} and thus causes an associated reduction in performance. Inverter design must be tuned to meet the specific needs of the intended application.

### Tenth Embodiment: Strained Silicon Devices in an Inverter with optimized SiGe ratios of the Relaxed SiGe for short and long channel devices.

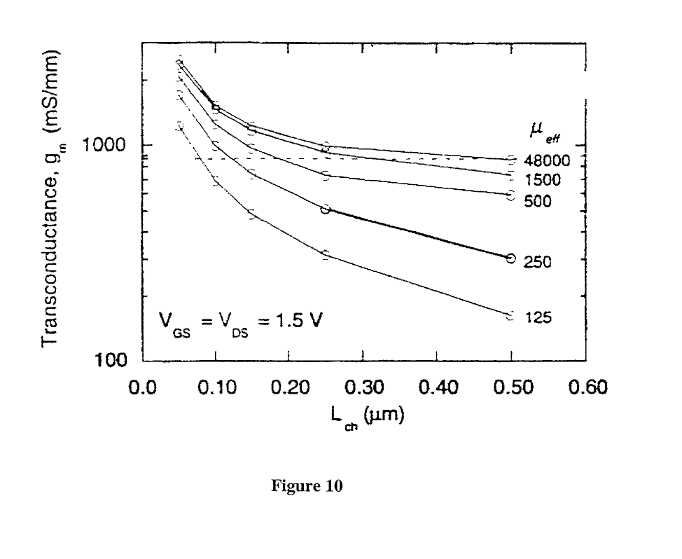

In short channel devices, the lateral electric field driving the current from the source to the drain becomes very high. As a result, the electron velocity approaches a limiting value called the saturation velocity, vₛₐₜ. Since strained silicon provides only a small enhancement in vₛₐₜ over bulk silicon, researchers believed that strained silicon would not provide a performance enhancement in short channel devices. However, recent data shows that transconductance values in short channel devices exceed the maximum value predicted by velocity saturation theories. FIG. 10 is a graph showing NMOSFET transconductance versus channel length for various carrier mobilities. The dashed line indicates the maximum transconductance predicted by velocity saturation theories. The graph shows that high low-field mobilities translate to high high-field mobilities. The physical mechanism for this phenomenon is still not completely understood; however, it demonstrates that short channel mobility enhancement can occur in strained silicon.

The power consumed in an inverter depends on both V_{DD} and tₚ. Therefore, as tₚ is decreased due to mobility enhancement, V_{DD} must also be decreased in order to maintain the same power consumption. In a long channel device, the average current, Iₐᵥ, is proportional to V_{DD}². Inserting this dependence into equation 3 reveals an inverse dependence of the propagation delay on V_{DD}. Thus, as the average current in strained silicon is increased due to mobility enhancement, the effect on the propagation delay is somewhat offset by the reduction in V_{DD}.

A comparison of the high-speed scenario device dominated capacitance inverter circuit shown in FIG. 7 to the constant V_{DD} scenario wiring capacitance dominated inverter circuit shown in FIG. 8 reveals the effect the reduced V_{DD} has on speed enhancement. In a short channel device, the average current is proportional to V_{DD} not V_{DD}², causing the propagation delay to have no dependence on V_{DD} (assuming V_{DD}>>V_{T}). As a result, mobility enhancements in a short channel, strained silicon inverter are directly transferred to a reduction in tₚ. A 1.2 μm strained silicon inverter on 30% SiGe experiences a 29.3% increase in device speed for the same power (FIG. 7).

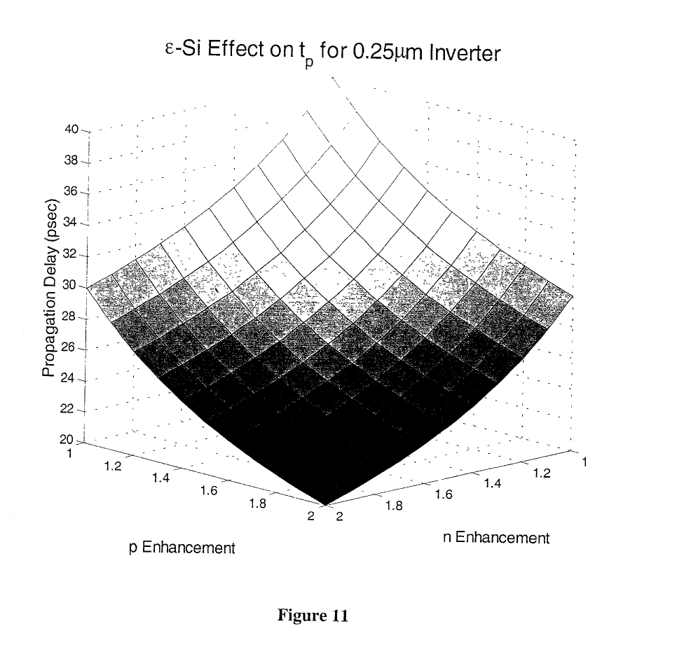

FIG. 11 is a graph showing the propagation delay of a short channel 0.25 μm CMOS inverter for a range of electron and hole mobility enhancements. Although the exact enhancements in a short channel device vary with the fabrication processes, FIG. 11 demonstrates that even small enhancements can result in a significant effect on tₚ.

### Eleventh Embodiment: Strained Silicon Devices in an Other Digital Gates with optimized SiGe ratios of the Relaxed SiGe.

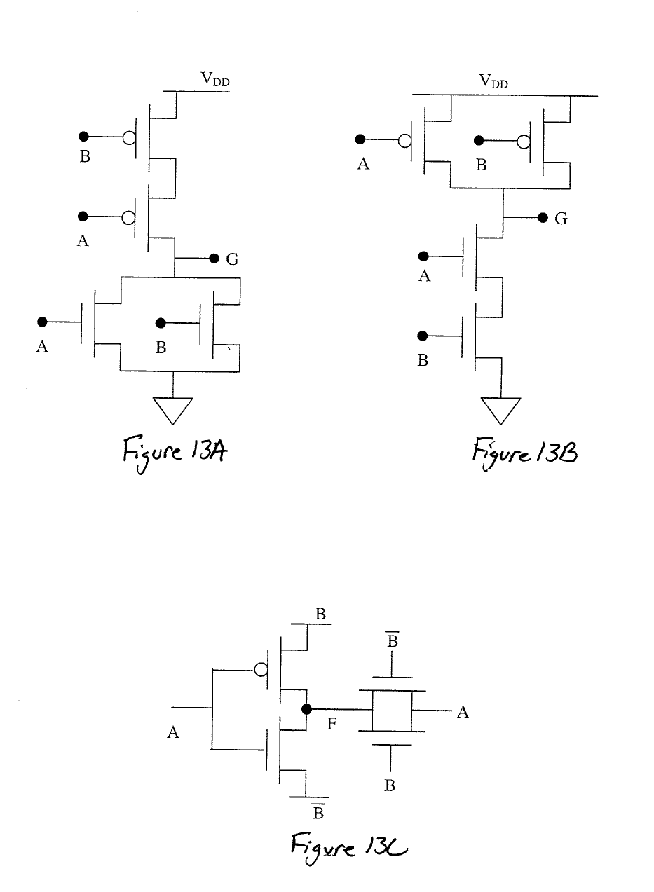

Although the preceding embodiments describe the performance of a CMOS inverter, strained silicon enhancement can be extended to other digital gates such as NOR, NAND, and XOR structures. Circuit schematics for a NOR gate 1300, a NAND gate 1302 and a XOR gate 1304 are shown in FIGS. 13A-C, respectively. The optimization procedures are similar to that used for the inverter in that the power consumption and/or propagation delay must be minimized while satisfying the noise margin and area requirements of the application. When analyzing these more complex circuits, the operation speed is determined by the worst-case delay for all of the possible inputs.

For example, in the pull down network of the NOR gate 1300 shown in FIG. 13A, the worst delay occurs when only one NMOS transistor is activated. Since the resistances are wired in parallel, turning on the second transistor only serves to reduce the delay of the network. Once the worst-case delay is determined for both the high to low and low to high transitions, techniques similar to those applied to the inverter can be used to determine the optimum design.

The enhancement provided by strained silicon is particularly beneficial for NAND-only architectures. As shown in FIG. 13B, in the architecture of the NAND gate 1302, the NMOS devices are wired in series while the PMOS devices are wired in parallel. This configuration results in a high output when either input A or input B is low, and a low output when both input A and input B are high, thus providing a NAND logic function. Since the NMOS devices are in series in the pull down network, the NMOS resistance is equal to two times the device resistance. As a result, the NMOS gate width must be doubled to make the high to low transition equal to the low to high transition.

Since electrons experience a larger enhancement than holes in strained Si, the NMOS gate width up scaling required in NAND-only architectures is less severe. For 1.2 μm strained silicon CMOS on a Si_{0.8}Ge_{0.2} platform, the NMOS gate width must only be increased by 14% to balance the pull down and pull up networks (assuming the enhancements shown in FIG. 6). Correspondingly, for 1.2 μm CMOS on Si_{0.7}Ge_{0.3}, the NMOS width must be increased by 55% since the n and p enhancements are more balanced. The high electron mobility becomes even more important when there are more than two inputs to the NAND gate, since additional series-wired NMOS devices are required.

Although the present invention has been shown and described with respect to several preferred embodiments thereof, various changes, omissions and additions to the form and detail thereof, may be made therein, without departing from the spirit and scope of the invention.

What is claimed is:

1. A CMOS inverter comprising:
a heterostructure including a Si substrate, a relaxed Si₁₋ₓGeₓ layer on said Si substrate, and a strained surface layer on said relaxed Si₁₋ₓGeₓ layer; and
a pMOSFET and an nMOSFET, wherein the channel of said pMOSFET and the channel of said nMOSFET are formed in said strained surface layer.

2. The CMOS inverter of claim 1, wherein the heterostructure further comprises a planarized surface positioned between the strained surface layer and the Si substrate

3. The CMOS inverter of claim 1, wherein the surface roughness of the strained surface layer is less than 1 nm

4. The CMOS inverter of claim 1, wherein the heterostructure further comprises an oxide layer positioned between the relaxed Si₁₋ₓGeₓ layer and the Si substrate

5. The CMOS inverter of claim 1, wherein the heterostructure further comprises a SiGe graded buffer layer positioned between the relaxed Si₁₋ₓGeₓ layer and the Si substrate

6. The CMOS inverter of claim 1, wherein the strained surface layer comprises Si

7. The CMOS inverter of claim 1, wherein 0.1<x<0.5

8. The CMOS inverter of claim 7, wherein the ratio of gate width of the pMOSFET to the gate width of the nMOSFET is approximately equal to the ratio of the electron mobility and the hole mobility in bulk silicon

9. The CMOS inverter of claim 7, wherein the ratio of gate width of the pMOSFET to the gate width of the nMOSFET is approximately equal to the ratio of the electron mobility and the hole mobility in the strained surface layer

10. The CMOS inverter of claim 7, wherein the ratio of gate width of the pMOSFET to the gate width of the nMOSFET is approximately equal to the square root of the ratio of the electron mobility and the hole mobility in bulk silicon

11. The CMOS inverter of claim 7, wherein the ratio of gate width of the pMOSFET to the gate width of the nMOSFET is approximately equal to the square root of the ratio of the electron mobility and the hole mobility in the strained surface layer

12. The CMOS inverter of claim 7, wherein the gate drive is reduced to lower power consumption

13. In a high speed integrated circuit, the CMOS inverter of claim 7

14. In a low power integrated circuit, the CMOS inverter of claim 7

15. An integrated circuit comprising:
a heterostructure including a Si substrate, a relaxed Si₁₋ₓGeₓ layer on said Si substrate, and a strained layer on said relaxed Si₁₋ₓGeₓ layer; and
a p transistor and an n transistor formed in said heterostructure, wherein said strained layer comprises the channel of said n transistor and said p transistor, and said n transistor and said p transistor are interconnected in a CMOS circuit.

16. The integrated circuit of claim 15, wherein the heterostructure further comprises a planarized surface positioned between the strained layer and the Si substrate

17. The integrated circuit of claim 15, wherein the surface roughness of the strained layer is less than 1 nm

18. The integrated circuit of claim 15, wherein the heterostructure further comprises an oxide layer positioned between the relaxed Si₁₋ₓGeₓ layer and the Si substrate

19. The integrated circuit of claim 15, wherein the heterostructure further comprises a SiGe graded buffer layer positioned between the relaxed Si₁₋ₓGeₓ layer and the Si substrate

20. The integrated circuit of claim 15, wherein the strained layer comprises Si

21. The integrated circuit of claim 15, wherein 0.1<x<0.5

22. The integrated circuit of claim 15, wherein the CMOS circuit comprises a logic gate

23. The integrated circuit of claim 15, wherein the CMOS circuit comprises a NOR gate

24. The integrated circuit of claim 15, wherein the CMOS circuit comprises an XOR gate

25. The integrated circuit of claim 15, wherein the CMOS circuit comprises a NAND gate

26. The integrated circuit of claim 15, wherein the p-channel transistor serves as a pull-up transistor in said CMOS circuit and the n-channel transistor serves as a pull-down transistor in said CMOS circuit

27. The integrated circuit of claim 15, wherein the CMOS circuit comprises an inverter

28. A method of fabricating a CMOS inverter comprising:
providing a heterostructure including a Si substrate, a relaxed Si₁₋ₓGeₓ layer on said Si substrate, and a strained surface layer on said relaxed Si₁₋ₓGeₓ layer; and
integrating a pMOSFET and an nMOSFET in said heterostructure, wherein the channel of said pMOSFET and the channel of said nMOSFET are formed in said strained surface layer.

29. The method of claim 28, wherein the heterostructure further comprises a planarized surface positioned between the strained surface layer and the Si substrate

30. The method of claim 28, wherein the surface roughness of the strained surface layer is less than 1 nm

31. The method of claim 28, wherein the heterostructure further comprises an oxide layer positioned between the relaxed Si₁₋ₓGeₓ layer and the Si substrate

32. The method of claim 28, wherein the heterostructure further comprises a SiGe graded buffer layer positioned between the relaxed Si₁₋ₓGeₓ layer and the Si substrate

33. The method of claim 28, wherein the strained surface layer comprises Si

34. The method of claim 28, wherein 0.1<x<0.5

35. The method of claim 34, wherein the ratio of gate width of the pMOSFET to the gate width of the nMOSFET is approximately equal to the ratio of the electron mobility and the hole mobility in bulk silicon

36. The method of claim 34, wherein the ratio of gate width of the pMOSFET to the gate width of the nMOSFET is approximately equal to the ratio of the electron mobility and the hole mobility in the strained surface layer

37. The method of claim 34, wherein the ratio of gate width of the pMOSFET to the gate width of the nMOSFET is approximately equal to the square root of the ratio of the electron mobility and the hole mobility in bulk silicon

38. The method of claim 34, wherein the ratio of gate width of the pMOSFET to the gate width of the nMOSFET is approximately equal to the square root of the ratio of the electron mobility and the hole mobility in the strained surface layer

39. The method of claim 34, wherein the gate drive is reduced to lower power consumption

40. A method of fabricating an integrated circuit comprising:
providing a heterostructure having a Si substrate, a relaxed Si₁₋ₓGeₓ layer on said Si substrate, and a strained layer on said relaxed Si₁₋ₓGeₓ layer; and
forming a p transistor and an n transistor in said heterostructure, wherein said strained layer comprises the channel of said n transistor and said p transistor, and said n transistor and said p transistor are interconnected in a CMOS circuit.

41. The method of claim 40, wherein the heterostructure further comprises a planarized surface positioned between the strained layer and the Si substrate

42. The method of claim 40, wherein the surface roughness of the strained layer is less than 1 nm

43. The method of claim 40, wherein the heterostructure further comprises an oxide layer positioned between the relaxed Si₁₋ₓGeₓ layer and the Si substrate

44. The method of claim 40, wherein the heterostructure further comprises a SiGe graded buffer layer positioned between the relaxed Si₁₋ₓGeₓ layer and the Si substrate

45. The method of claim 40, wherein the strained layer comprises Si

46. The method of claim 40, wherein 0.1<x<0.5

47. The method of claim 40, wherein the CMOS circuit comprises a logic gate

48. The method of claim 40, wherein the CMOS circuit comprises a NOR gate

49. The method of claim 40, wherein the CMOS circuit comprises an XOR gate

50. The method of claim 40, wherein the CMOS circuit comprises a NAND gate

51. The method of claim 40, wherein the p-channel transistor serves as a pull-up transistor in said CMOS circuit and the n-channel transistor serves as a pull-down transistor in said CMOS circuit

52. The method of claim 40, wherein the CMOS circuit comprises an inverter

53. A method of fabricating a CMOS inverter comprising:
providing a graded Si₁₋ₓGeₓ layer on a first Si substrate;
providing a relaxed Si_{1-y}Ge_{y} layer on said graded layer to form a first structure;
bonding said relaxed layer of said first structure to a second structure that includes a second Si substrate;
removing said first Si substrate and said graded layer;
providing a strained surface layer on said relaxed layer to form a heterostructure; and
integrating a pMOSFET and an nMOSFET in said heterostructure, wherein the channel of said pMOSFET and the channel of said nMOSFET are formed in said strained surface layer

54. A method of fabricating an integrated circuit comprising:
providing a graded Si₁₋ₓGeₓ layer on a first Si substrate;
providing a relaxed Si_{1-y}Ge_{y} layer on said graded layer to form a first structure;
bonding said relaxed layer of said first structure to a second structure that includes a second Si substrate;
removing said first Si substrate and said graded layer;
providing a strained surface layer on said relaxed layer to form a heterostructure; and forming a p transistor and an n transistor in said heterostructure, wherein said strained layer comprises the channel of said n transistor and said p transistor, and said n transistor and said p transistor are interconnected in a CMOS circuit.
